(19) United States
(12) Patent Application Publication
(10) Pub. No.: US 2005/0181310 A1
(43) Pub. Date: Aug. 18, 2005

(54) Method for etching metal surface of golf club head

(76) Inventors: Shun-Fa Yang, Kaohsiung Hsien (TW); Chan-Tung Chen, Kaohsiung (TW)

Correspondence Address: BIRCH STEWART KOLASCH & BIRCH, PO BOX 747, FALLS CHURCH, VA, 22040-0747, US

(21) Appl. No.: 10/778,404

(22) Filed: Feb. 17, 2004

(51) Int. Cl. G03F 7/00

(52) U.S. Cl. 430/320; 430/323

(57) ABSTRACT

A method for etching a metal surface of a golf club head includes coating a masking layer on a metal surface of a golf club head, illuminating the masking layer with laser beams to form windows of a predetermined pattern, etching areas of the metal surface exposed via the windows to form the predetermined pattern in the metal surface, and removing the masking layer. A predetermined patter is thus formed on a metal surface of the golf club head with improved etching accuracy, expedited etching procedure, improved etching effect, and reduced etching cost.

### BACKGROUND OF THE INVENTION

1. Field of the Invention

The present invention relates to a method for etching a surface of a golf club head. In particular, the present invention relates to an etching method for forming a predetermined pattern on a metal surface of a golf club head.

2. Description of Related Art

A surface of a golf club head can be engraved or etched according to need by means of CNC (computer numerical control) engraving, screen printing, mask etching, shot peening, or laser engraving so as to engrave or etch a surface of the body, striking plate, or hosel of the golf club head. The engraving or etching is carried out to form several channels on a front side of the striking plate for increasing friction and accuracy during striking. Another advantage includes forming a complicated pattern on the rear side of the striking plate for aesthetic purposes.

One of the disadvantages of the conventional CNC engraving is that the channels engraved by the cutter used in the CNC engraving has a depth greater than 0.1 mm due to limitation resulting from the size of the cutter and due to difficult control of the milling strength. Further, when horizontal positioning of the striking plate is not precisely carried out, the processing depth and the processing width of the cutter would not be precise, failing to provide uniform products. Further, the cutter gradually wears or even breaks during the processing procedure, which leads to an increase in the disqualified products. Further, the cutting mark on the golf club head by the cutter adversely affects the appearance and makes the edges of the pattern coarser, leading to stress concentration on the pattern and to weakening of the strength of the striking plate. Further, since the CNC processing can only form deeper channels, the strength of the striking plate is adversely affected when the striking plate to be processed is thin. Hence, CNC processing is not suitable for manufacturing golf club heads of the type having a thin striking plate.

Typical screen printing includes the steps of: preparing a screen having a pattern complementary to the predetermined pattern, printing the complementary pattern of the screen onto the striking plate, etching the striking plate by ordinary chemical etching to form the predetermined pattern, removing the printed pattern on the striking plate, and cleaning the surface of the striking plate. Despite of the advantage of low manufacturing cost, screen printing is not suitable for forming delicate patterns, as various controlling parameters including the printing force, the orientation of a scraper plate, the level of the screen are manually operated. Product uniformity could not be improved.

Mask etching is usually used in manufacture of integrated circuits and includes the steps of: preparing a mask with a predetermined pattern (or complementary pattern), coating a photo resist (negative or positive) on a substrate, placing the mask on top of the substrate and proceeding with exposure to cause photoreaction of a portion of the photo resist associated with the predetermined pattern (or complementary pattern), dissolving the remaining portion of the photo resist to make the photo resist form the predetermined pattern, carrying out ordinary chemical etching on the substrate to form the predetermined pattern, removing the photo resist, and cleaning the surface of the substrate. Although the mask etching may generate delicate patterns and provide more uniform products, the procedures are complicated and costly, which are detrimental to expedition of the manufacturing procedure and to mass production.

Shot peening includes repetitious engraving to form channels deeper or shallower than 0.1 mm, which is suitable for engraving striking plates of various thicknesses. However, shot peening is time-consuming and could not form delicate patterns. Further, residual stress may exist when carrying out shot peening continuously, and permanent deformation of the striking plate may be caused.

Laser engraving also includes repetitious engraving to form channels deeper or shallower than 0.1 mm. Although more delicate patterns can be formed by laser engraving, the procedure is time-consuming. In a case that deeper engraving is required, the high-power laser beams for engraving generates outwardly radiating high heat that affects the area of the metal material being engraved, causing a change in the physical properties and the metal phase of this area. As a result, the striking plate is weakened, and the coefficient of restitution of the striking plate is reduced.

### OBJECT OF THE INVENTION

An object of the present invention is to provide a method for etching a metal surface of a golf club head to form a predetermined patter on a metal surface of the golf club head with improved etching accuracy, expedited etching procedure, improved etching effect, and reduced etching cost.

### SUMMARY OF THE INVENTION

In accordance with an aspect of the present invention, a method for etching a metal surface of a golf club head comprises coating a masking layer on a metal surface of a golf club head, illuminating the masking layer with laser beams to form windows of a predetermined pattern, etching areas of the metal surface exposed via the windows to form the predetermined pattern in the metal surface, and removing the masking layer.

The metal surface is cleaned after removing the masking layer. The metal surface may be a front side or a rear side of a body, a striking plate, and a hosel of the golf club head.

In an embodiment of the invention, the masking layer is an insulating layer of a material resistant to etching. The material is insulating paint, wax, or high molecular polymer painting. The insulating layer may be coated by spin coating, spraying, immersion, or printing.

In another embodiment of the invention, the masking layer is a positive resist layer. The positive resist layer is illuminated with the laser beams to form photoreactive areas of the predetermined pattern. The photoreactive areas are removed by an exposure liquid to form the windows of the predetermined pattern.

In a further embodiment of the invention, the masking layer is a negative resist layer. The negative resist layer is illuminated with the laser beams to form photoreactive areas complementary to the predetermined pattern. The negative resist layer except for the photoreactive areas is removed by an exposure liquid to form the windows of the predetermined pattern.

Preferably, the laser beams have a power between 1 W and 200 W. Suitable sources for providing the laser beams include liquid laser, solid laser, and gaseous laser, such as a CO₂ laser.

Other objects, advantages and novel features of this invention will become more apparent from the following detailed description when taken in conjunction with the accompanying drawings.

### BRIEF DESCRIPTION OF THE DRAWINGS

FIG. 1 is a flow chart illustrating a method for etching a surface of a golf club head in accordance with the present invention;

FIG. 2 is an exploded perspective view of a golf club head manufactured by the method in accordance with the present invention;

FIG. 3 is another exploded perspective view of the golf club head manufactured by the method in accordance with the present invention;

FIGS. 4A through 4D are sectional views illustrating the steps of the method in accordance with the present invention;

FIGS. 5A through 5E are sectional views illustrating the steps of a modified embodiment of the method in accordance with the present invention; and

FIGS. 6A through 6E are sectional views illustrating the steps of another modified embodiment of the method in accordance with the present invention.

### DETAILED DESCRIPTION OF THE PREFERRED EMBODIMENTS

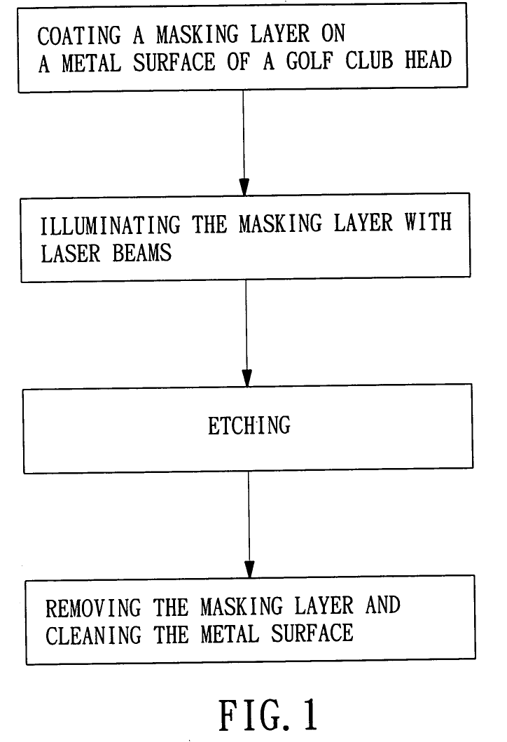

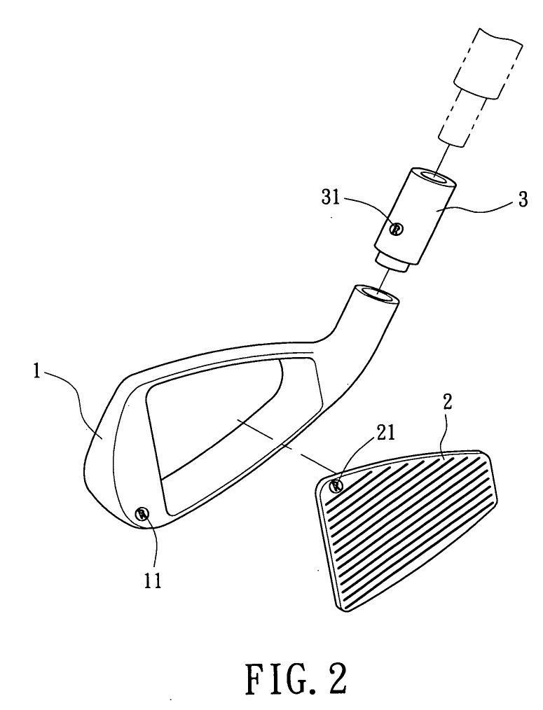

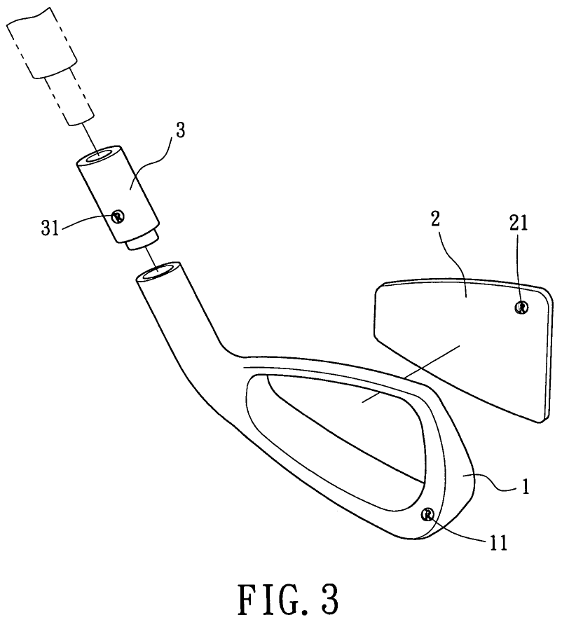

Referring to FIGS. 1 through 3, a first step of a first embodiment of a method for etching a surface of a golf club head in accordance with the present invention includes coating a masking layer on a surface of a golf club head. The surface can be any metal surface on a golf club head, such as the front side or rear side of a body 11, a striking plate 2, or a hosel 3 of the golf club head. Further, the surface is preferably made of carbon steel, special steel, titanium alloy, or stainless steel. A predetermined pattern can be formed on the selected surface by the method in accordance with the present invention. As illustrated in FIGS. 2, 3, and 4A, in a case that a predetermined pattern 21 is to be formed on a front side or a rear side of a striking plate 2, an insulating layer 4 is firstly applied to the front side or rear side of the striking plate 2 as the masking layer. The insulating layer 4 is preferably formed of an insulating layer of a material that is resistant to etching or non-reactive to etchant, such as insulating paint, wax, high molecular polymer paint. The insulating material is coated by spin coating, spraying, immersion, printing, etc. After drying of the insulating material, an insulating layer 4 (the masking layer) is formed on a predetermined area of the metal surface on the striking plate 2.

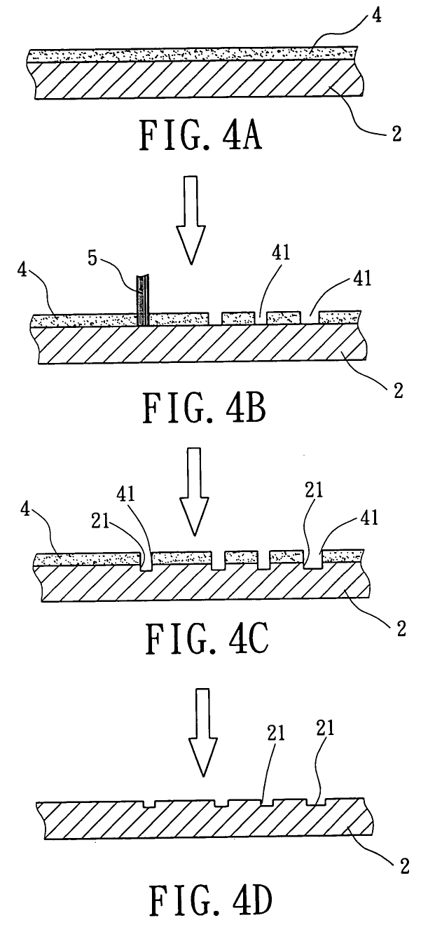

Referring to FIGS. 1 and 4B, in a second step of the method in accordance with the present invention, the masking layer is illuminated by laser beams 5 to form windows 41 of the predetermined pattern in the masking layer (the insulating layer 4). Preferably, the laser beams 5 have a low power between 1 W and 200 W. Suitable sources for the laser beams 5 include liquid laser, solid laser, and gaseous laser, such as a CO₂ laser that can rapidly drill holes in the insulating layer 4 and that has a wavelength cannot be absorbed by the metal surface and thus cause no damage to the metal surface. The laser beams 5 can be of pulse type or continuous wave type and has a focused light-spot with a fineness as small as 0.01 mm. Due to low power of the laser beams 5 that can only penetrate the insulating layer 4 (the masking layer), the drilling procedure can be rapidly completed without damaging the metal surface. Further, the path of the laser beams 5 can be set according to the product need, thereby forming appropriate windows 41 corresponding to the predetermined pattern. The accuracy and fineness of the windows 41 are improved by the laser beams 5 with a small spot. Thus, the qualified product rate is increased, and the product uniformity is improved.

Referring to FIGS. 1 and 4C, a third step of the method in accordance with the present invention is etching areas of the metal surface that are exposed via the windows 41, thereby obtaining the predetermined pattern 21 in the metal surface. The etchant for proceeding with the etching procedure can be selected according to the metal material of the striking plate 2. When the striking plate 2 is immersed into the etchant, the areas of the metal surface are etched by the etchant to form the predetermined pattern 21. Concentration of the etchant, the etching time, and the etching temperature can be appropriately controlled to form the predetermined pattern 21 with desired etching depth. Further, the spacing between the channels constituting the patterns 21 is preferably greater than the etching depth. Further, the ratio of the etched area to the unetched area can be controlled to provide an appearance with “layering effect” and various brightness effects.

Referring to FIGS. 1 and 4D, a fourth step of the method in accordance with the present invention is removing the masking layer (the insulating layer 4) and cleaning the metal surface. An appropriate organic solvent is selected to remove the residual insulating layer 4 on the striking plate 2. Water and cleaning agent are used to clean the metal surface of the striking plate 2. The striking plate 2 after processing has a predetermined pattern 21 on a front side or rear side thereof. The method in accordance with the present invention can be applied on any surface of the body 1 or the hosel 3 to form any desired pattern 11, 31.

The method in accordance with the present invention includes several advantages. Firstly, coating of the insulating layer 4 (the masking layer) can be rapidly completed and the procedure is expedited, as there is no need to form the predetermined pattern in the insulating layer 4 at first. Second, drilling by the low-power laser beams 5 is highly accurate and highly fine, which also expedites the procedure. Further, the path of the laser beams 5 can be rapidly adjusted to change the pattern. Further, ordinary chemical etching that allows easy control of the etching conditions (including etching depth), that provides product uniformity, and that has a low cost can be used in the method in accordance with the present invention.

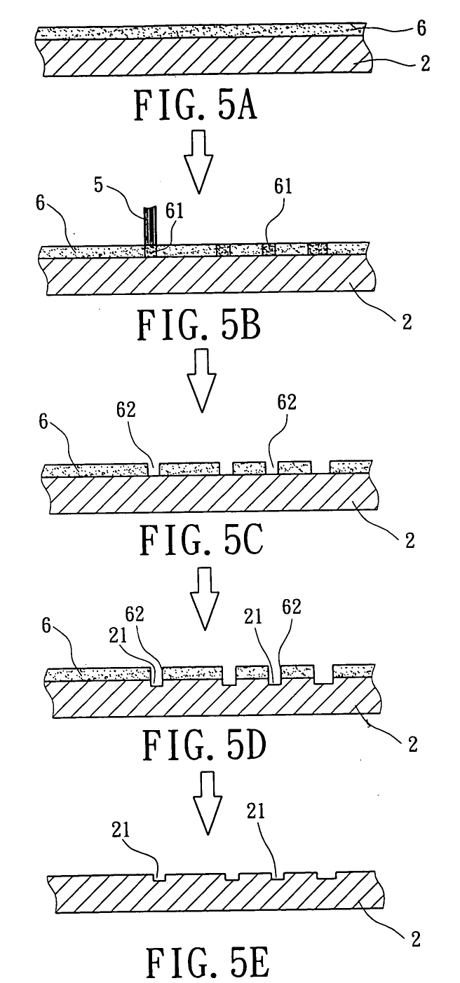

FIGS. 5 through 5E illustrate a modified embodiment of the method in accordance with the present invention. In this embodiment, a photo resist is coated on the metal surface to form the masking layer. The photo resist is a positive resist. The areas of the masking layer of photo resist illuminated by the laser beams 5 are decomposed as a result of photoreaction caused by the laser beams 5. The decomposed photo resist can be dissolved by ordinary exposure liquid. In particular, the modified embodiment of the method in accordance with the present invention includes the steps of: coating a photo resist layer 6 (masking layer) on a metal surface of a golf club head (FIG. 5A), illuminating the photo resist layer 6 (masking layer) with laser beams 5 to form photoreactive areas 61 of a predetermined pattern (FIG. 5B), removing the photoreactive areas 61 by an appropriate exposure liquid to form windows 62 of the predetermined pattern. (FIG. 5C), etching areas of the metal surface that are exposed via the windows 62, thereby obtaining the predetermined pattern 21 in the metal surface (FIG. 5D), and removing the photo resist layer 6 (masking layer) and cleaning the metal surface (FIG. 5E). The positive resist and exposure liquid are conventional in the circuit board technology and the wafer processing technology and therefore not described in detail.

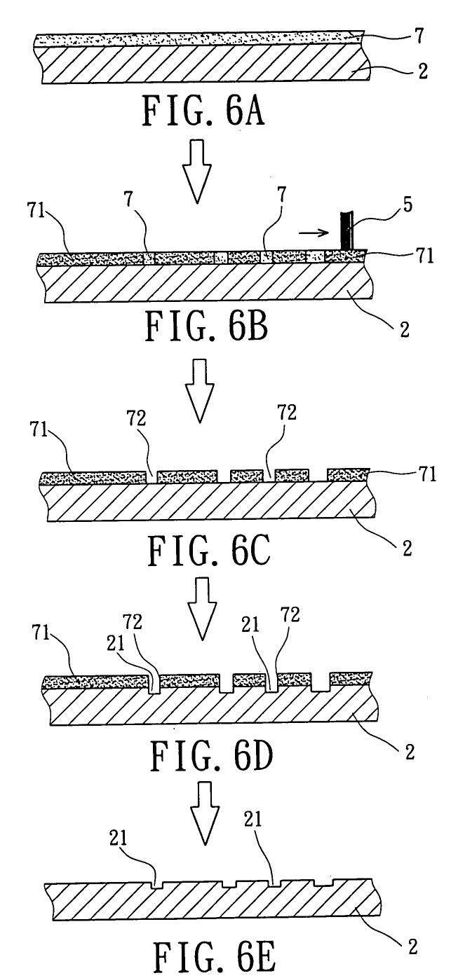

FIGS. 6 through 6E illustrate another modified embodiment of the method in accordance with the present invention. In this embodiment, a photo resist is coated on the metal surface to form the masking layer. The photo resist is a negative resist. Photoreaction is caused in the areas of the masking layer of photo resist illuminated by the laser beams 5. Recombination occurs or a bridge is formed. The resultant composition cannot be or is difficult to be dissolved by ordinary exposure liquid. In particular, this modified embodiment of the method in accordance with the present invention includes the steps of: coating a photo resist layer 7 (masking layer) on a metal surface of a golf club head (FIG. 6A), illuminating the photo resist layer 7 (masking layer) with laser beams 5 to form photoreactive areas 71 complementary to a predetermined pattern (FIG. 6B), removing the photo resist layer 7 except for the photoreactive areas 71 by an appropriate exposure liquid to form windows 72 of the predetermined pattern (FIG. 6C), etching areas of the metal surface that are exposed via the windows 72, thereby obtaining the predetermined pattern 21 in the metal surface (FIG. 6D), and removing the photo resist layer 7 (masking layer) and cleaning the metal surface (FIG. 6E). The negative resist and exposure liquid are conventional in the circuit board technology and the wafer processing technology and therefore not described in detail.

As apparent from the foregoing, by means of the method in accordance with the present invention including the steps of coating a masking layer, drilling with laser beams, and chemical etching, the etching accuracy is improved, the etching procedure is expedited, the etching effect is improved, and the etching cost is reduced.

While the principles of this invention have been disclosed in connection with specific embodiments, it should be understood by those skilled in the art that these descriptions are not intended to limit the scope of the invention, and that any modification and variation without departing the spirit of the invention is intended to be covered by the scope of this invention defined only by the appended claims.

1. A method for etching a metal surface of a golf club head, comprising:
coating a masking layer on a metal surface of a golf club head;
illuminating the masking layer with laser beams to form windows of a predetermined pattern;
etching areas of the metal surface exposed via the windows to form the predetermined pattern in the metal surface; and
removing the masking layer.

2. The method as claimed in claim 1, wherein the golf club head includes a body, a striking plate, and a hosel, and wherein the metal surface includes one of a front side and a rear side of one of the body, the striking plate, and the hosel.

3. The method as claimed in claim 1, wherein the masking layer is an insulating layer.

4. The method as claimed in claim 3, wherein the insulating layer is a layer of a material resistant to etching.

5. The method as claimed in claim 4, wherein said material is one of insulating paint, wax, and high molecular polymer painting.

6. The method as claimed in claim 3, wherein the insulating layer is coated by one of spin coating, spraying, immersion, and printing.

7. The method as claimed in claim 1, wherein the masking layer is a layer of photo resist.

8. The method as claimed in claim 7, wherein the masking layer is formed by means of coating a layer of one of a positive resist and a negative resist.

9. The method as claimed in claim 8, wherein the masking layer is a positive resist layer, the positive resist layer being illuminated with the laser beams to form photoreactive areas of the predetermined pattern, the photoreactive areas being removed by an exposure liquid to form the windows of the predetermined pattern.

10. The method as claimed in claim 8, wherein the masking layer is a negative resist layer, the negative resist layer being illuminated with the laser beams to form photoreactive areas complementary to the predetermined pattern, the negative resist layer except for the photoreactive areas being removed by an exposure liquid to form the windows of the predetermined pattern.

11. The method as claimed in claim 1, wherein the laser beams have a power between 1 W and 200 W.

12. The method as claimed in claim 1, wherein a source for providing the laser beams is one of liquid laser, solid laser, and gaseous laser.

13. The method as claimed in claim 12, wherein the source for providing the laser beams is a CO₂ laser.

14. The method as claimed in claim 1, further including a step of cleaning the metal surface after removing the masking layer.
